(19) United States
(12) Patent Application Publication
(10) Pub. No.: US 2012/0066956 A1
(43) Pub. Date: Mar. 22, 2012

(54) TERMINAL FLY FISHING TACKLE

(75) Inventors: Staale Petter Lyngstadaas, Nedoddtangen (NO); Sébastien Francis Michel Taxt-Lamolle, Oslo (NO); Hävard J. Haugen, Oslo (NO); Ernstpeter Stüven, Rorbas (CH)

(73) Assignee: AboBelo DA, Nesoddtangen (NO)

(21) Appl. No.: 13/322,586

(22) PCT Filed: May 28, 2010
(86) PCT No.: PCT/EP2010/057426

§ 371 Date: Nov. 28, 2011

(30) Foreign Application Priority Data
May 29, 2009 (SE) 09503897

(51) Int. Cl. A01K 85/08; B05D 1/36; C23C 16/56; C23C 16/40; C23C 16/44

(52) U.S. Cl. 43/42.25; 427/248.1; 427/553; 427/554; 427/419.2

(57) ABSTRACT

Terminal fishing tackle, such as lines, leaders bait, lures, nymphs, streamers, zonkers, muddlers and/or flies, made from natural and/or synthetic fibres and coated with one or more uniform nano-thin, pin hole free metal oxide layers. More particularly, the terminal fishing tackle has fibres that are coated with one or more nano-composite reinforcing layers of metal oxides that convey hydrophobic, hydrophilic, super hydrophilic, water sealant, waterproof, photocatalytic, UV-protecting, anti-microbial, and/or anti-fouling properties, wherein said coatings are gained by using atomic layer deposition techniques on said tackle. In a preferred embodiment, said coating is selected from Carbon, Gold, Palladium, TiO₂, SiO₂ and Al₂O₃ or combinations thereof.

### FIELD OF THE INVENTION

The present invention relates to the field of terminal fishing tackle, such as leaders, bait, lures and/or flies, made from natural and/or synthetic fibres and coated with a uniform nano-thin metal oxide layer. More particularly, the present invention relates to terminal fishing tackle that has a hydrophobic, hydrophilic, super hydrophilic, water sealant, colour introducing, photocatalytic, UV-protecting, anti-microbial, and/or anti-fouling property, wherein said property is gained by a coating using advanced methods for atomic layer deposition, or combinations of atomic layer deposition and additional coating on said tackle. In a preferred embodiment, said coating is selected from Carbon, Gold, Palladium, TiO₂, Al₂O₃, SiO₂ and combinations thereof.

### BACKGROUND TO THE INVENTION

There are many different styles of fishing and many of them involve the use of a line, and a lure, spinner, artificial fly or other attractant. Fly fishing is a style of fishing in which a very light weight “fly” is attached to the end of a fishing line. The word “fly” is used to describe the device that attracts the attention of the fish and causes it to strike. This “fly” can be a construction which is designed to simulate the general shape, colour, size, and look of a fly or other insect or nymph or spawn or small fish which is naturally occurring in the fish's environment.

In fly fishing, the fishing line at the point of attachment to the fly is typically monofilament and very fine, and gradually tapers to a thicker diameter toward the fisherman. The portion closest to the fisherman is typically a thicker and heavier section of line, is coloured and opaque, and may float on water or sink, or just the tip may sink. This heavier line is threaded through the eyelets on a fishing pole and is wound on a fishing reel which is held near the fisherman's hand on the pole. Using the fly fishing method of fishing, the rod, which is a very flexible device of varying lengths and diameters, is used in a whip-like fashion to extend the heaviest section of fishing line to a point where the fisherman believes the fish may see the fly or be in hiding in wait for food. The rod is used to whip the heavy line back and forth until enough line is extended that if it is allowed to drop to the water, the fly will be in proper position in front of or above the fish.

Because of the whipping action of fly fishing, the fly must be very light in weight, since it is the heavier portion of the line which is cast, and the fly is just carried along with it. The light weight of a fly does not interfere with whipping the line back and forth, and also allows certain flies to float on top of the water and not sink beneath the water. This floating action aids in the simulation of natural insects and results in a more natural presentation to the fish. Because of the need for light weight materials in the fly so that it can be whipped back and forth with the line and so that it will lay on the water without sinking like its natural counterpart would, flies are typically made using extremely light weight material such as animal hair, birds' feathers, and sometimes foam for wings. Other flies are designed to sink, and may even have weight attached to aid in sinking.

What all artificial flies have in common is that they are tied to the hook using knots and some type of string. This is time consuming and requires a potentially vast inventory of a variety of materials and tools for tying material on the hook.

To create flashy colours which cause a fish to strike at it out of a protective instinct or from an aggressive instinct, various threads, strings, films, tape and tinsel are used which can be luminescent, fluorescent, neon, pearlescent, reflective, shiny or glittery. Such materials are used in various combinations to create any shape, pattern, or colour desired. Achieving these simulations is time consuming and intricate work and requires a large inventory of materials.

Another problem created by traditional fly tying methods is that when a body part on the fly is a large and bulky body part, the typical fly tying materials which are used to simulate this body part are such things as thread, pile, fur, feathers, etc. These materials are water absorbent and cause the body of such a fly to become heavy when it is water logged. This results in difficulty when casting, since the basis of casting in fly fishing is to cast the heavier portion of the line, rather than the fly. The fly must be very light in weight so as not to interfere with the casting of the line. A bulky fly which is soaked with water may interfere with proper casting technique. Moreover, a fly soaked with water will not float anymore above water level, but sink. A floating fly, said dry fly should not sink: in this case, it is not usable anymore and must be dried by the fisherman, or changed.

On the other hand, sometimes it is desirable that a fly sink quickly. For instance, if a person is casting upstream he might want his fly to sink quickly to the bottom of the river or stream to a depth at which the bigger fish are likely to see it. To facilitate this fast sinking, weights can be incorporated into the design of the fly in the form of beads of lead, bismuth, or other heavy material. Sometimes a fisherman may decide in the field that he needs more weight in a fly, and he can attach strips of thin weighted material such as lead, bismuth or other materials. Either weighted beads or weighted strips are usually tied on to the fly to add weight. The tying is time consuming, and can result in a fly with an un-natural appearance.

Traditionally, flies can be made water resistant by the use of water repellents, such as different oil-based ointments, or by impregnating the flies or coating them with shellac, The fisherman might even coat the flies with mud to achieve a desired result in bounce. All above outlined methods will leave the flies with an unnatural smell or taste, or with an oily appearance that is believed to scare away fish during the initial usage of the terminal tackle and also to potentially pollute rivers and lakes.

What is more, all the materials used in traditional fly tying are more or less constantly exposed to water, UV light, fungus bacteria, salt, or other plankton, and thus have a high tendency to rot or to brittle. Thus, the dedicated fisherman spends a vast amount of time and money on replenishing his or her stock of terminal fishing tackle.

Accordingly, it would be highly desirable to be able to produce artificial flies in which body parts of the flies are of the desired colour and shape, are light in weight, do not absorb water, and have a longer durability.

Another problem that is frequently encountered is keeping the lines adequately waterproofed or “waxed” to prevent the same from sinking which, should such occur, will prevent or greatly hinder normal use of the equipment.

Additionally, fly lines are susceptible to becoming coated with surface scum since the line is supported by the surface tensioning of the water or at least floats on the surface thereof rather than being submerged as cast lines normally are.

As is well known, a fly fishing line that features a very low specific gravity floats higher on the surface of the water thus allowing the angler to pick the fly line up off the water with greater ease. When the tip of the fly fishing line sinks, initiating a cast is difficult since greater energy must be applied to the line throughout the rod in order to remove the line from the water. A fly line that floats higher on the surface of the water thereby decreases surface tension and friction of the water when initiating a cast. Additionally, a fly fishing line with a high floating tip reduces the occurrence of the butt of a nylon leader attached to the high floating tip of the fly line from sinking. When the leader butt sinks, it submerges the tip of the fly fishing line making initiating the cast more difficult due to the increased friction created by the leader being pulled up through the water column. Furthermore, the tip of a high floating line is easier to see thus making it easier for the angler to detect a fish taking the fly when fishing subsurface flies.

Accordingly, it would be highly desirable to be able to produce fly fishing lines that float higher, are more durable, are suppler and perform better than currently available lines.

TiO₂, titanium (IV) oxide or titania is the naturally formed oxide of titanium and a very well-known and well-researched material due to the stability of its chemical structure, its biocompatibility, and physical, optical and electrical properties. Titanium dioxide occurs in nature as the well-known naturally occurring minerals rutile, anatase and brookite. Zinc oxide and titanium dioxide, particularly in the anatase form, are photocatalysts under ultraviolet light (UV). This has been discussed for example in Maness et al., 1999 (Applied and Environmental Microbiology, September 1999, p. 4094-4098). It was recently found that titanium dioxide, when doped with nitrogen ions or with metal oxide like wolfram trioxide, is also a photocatalyst under visible light. The strong oxidative potential of the positive holes oxidizes water to create hydroxyl radicals. It can also oxidize oxygen or organic materials directly. Moreover, free radicals possess antimicrobial and anti-fouling attributes.

In order to deposit titania onto a suitable catalyst support, researchers have investigated and developed various techniques and methods such as anodization, electrodeposition, sol-gel, reactive dc magnetronic sputtering, chemical vapour deposition, electrostatic sol-spray deposition and aerosol pyrolysis. The process of selecting a suitable deposition method depends on the type of catalyst support. (G. Li. Puma et al., Journal of Hazardous materials 157 (2008) 209-219.) For example Hemissi et al. discloses a method for deposing thin layers of titanium dioxide by a dip-coating method (sol-gel method) (Hemissi et al, Digest Journal of Nanomaterials and Biostructures, 2, (2007) 299-305).

Up to now, coatings of nano-thin metal oxides onto soft fibres have been unsuccessful. Different techniques such as Sol-Gel casting has been tried, but the resulting coatings have all been too thick and brittle, and not bound strongly enough to the coated material, causing the coating to flake off when the fibres or fabrics are manipulated.

Atomic Layer Deposition (ALD) is a technique that deposits films by one atomic layer at a time, allowing process control to achieve ultra thin films. In ALD, reactants are introduced one at a time, with pump/purge cycles in between. ALD reactions are self-saturating surface reactions, limited only to a single layer on the exposed surface to result in a up to 100% conformal pin-hole free film. Sequential cycles of these reactions enable thickness to be controlled very precisely even at the sub-nanometer level.

Aarik et al. (Journal of Crystal Growth 148 (1995), 268-275) discloses the deposition of films of TiO₂ by the use of ALD technology, wherein the layers produced are between 2 to 560 nm.

JP2000217483 describes an alternative method to produce coated fishing lines by use of a PVD method of depositing thin films by sputtering, i.e. ejecting, material from a “target,” i.e., source, onto a material. The availability of many parameters that control sputter deposition makes it a complex process, but equally allows experts a large degree of control over the growth and microstructure of the film. The disadvantage is that this technique has a shadowing effect, meaning only the surface adjacent to the sputtering target is coated. Therefore, the technique is not suitable for flies at all because of the multi-dimensionality of these objects. Also, this technique does not produce pin-hole free metal oxide layers, and the metal oxide layers are also not as nano-thin, nor as homogeneous as the once produced with the ALD technique. Consequently, sputter-coated fishing lines will eventually absorb water and sink.

### SUMMARY OF THE INVENTION

The present invention elegantly solves the above described long felt needs in the field by coating terminal fishing tackle or components thereof with a uniform nano-thin, homogenous, pin hole free and substantially amorphous metal oxide layer, which renders the terminal fishing tackle essentially water-proof as well as either hydrophobic or hydrophilic and/or adds antimicrobial and/or anti-fouling attributes to the material. Thus, the present invention for the first time discloses artificial flies in which body parts of the flies are of the desired colour and shape, are light in weight, do not absorb water, and have a longer durability. The present invention further also relates to fly fishing lines that do not absorb water, float higher, are more durable, are suppler and perform better than currently available lines.

The present invention relates to the field of terminal fishing tackle, such as lines, leaders, bait and/or flies, made from a core comprising natural and/or synthetic fibres and which is at least partially coated with at least one uniform nano-thin, homogenous, pin hole free and substantially amorphous metal oxide layer. The present invention in detail describes a terminal fishing tackle, comprising a core fibre and/or fabric at least partially coated with a uniform nano-thin, homogenous, pin hole free and substantially amorphous metal oxide layer, wherein the coating has a thickness of 200 nm or less. More particularly, the present invention relates to a terminal fishing tackle that displays hydrophobic, hydrophilic, hyper hydrophilic, water impermeable, water sealant, colour introducing, photocatalytic, UV-protecting, anti-microbial, anti-viral, and/or anti-fouling properties, wherein said one or more property is gained by using atomic layer deposition (ALD) technique for depositing at least one permanent nano-thin layer of composite reinforcement coating, such as an essentially homogenous, pin hole free and substantially amorphous metal oxide layer and/or film, onto said core material. In a preferred embodiment, said coating is selected from Carbon, Gold, Palladium, TiO₂, Al₂O₃, SiO₂ and combinations thereof.

The said layer(s) can be applied directly to the material that is used to produce the terminal fishing tackle, or, in a presently preferred embodiment, can be directly applied to the completed terminal tackle (e.g. complete fly with hook) without any harm to the tackle or material. One of the main advantages of the present invention over prior known terminal fish tackle is further that the shape, composition, and/or size of said tackle has virtually no impact on the distribution and homogeneity of the applied surface layer, nor are the mechanical properties of the material significantly and/or adversely changed. This is in starch contrast e.g. to a layering with sputter coating techniques, which will only deposit a layer onto surfaces of the tackle that are not shadowed by other surfaces and which are directly facing the source of the sputter. The uniform nano-thin, homogenous, pin hole free and substantially amorphous metal oxide layer is further stable, insoluble and does not convey any substantial taste, smell or other effect that might scare off the catch and/or damage the environment.

The proposed invention thus provides improved terminal fly fishing tackle which comprises a natural and/or synthetic core fabric and/or fibre which is at least partially coated with a layer comprising a uniform, nano-thin, homogenous, pin hole free and substantially amorphous metal oxide layer comprising in a presently preferred embodiment predominantly titanium oxide and has a thickness of 200 nm or less. In one aspect, said metal oxide layer additionally comprises one or more compounds selected from the group consisting of N, C, S, F, Cl, W and/or one or more compounds selected from the group consisting of F, Cl, Si and N, and/or one or more compounds selected from the group consisting of Ag, Au, Pd, Pt, Fe, Cl, F, Pb, Zn, Zr, B, Br, Si, Cr, Hg, Sr, Cu, I, Sn, Ta, W, Co, Mg, Mn, Si and Cd and/or one or more compounds selected from the group consisting of SnO₂, CaSnO₃, FeGaO₃, BaZrO₃, ZnO, WO₃, Nb₂O₅, CdS, ZnO₂, SrBi₂O₅, BiAlVO₇, ZnInS₄, K₆Nb_{10.8030}, Si₃N₄, SiC, SiH₄, SiF₂, Si₂O and/or a combination of compounds selected from said groups of compounds, wherein said one or more compound(s) selected from one or more group(s) of compounds are dispersed substantially homogenous within, onto, or between said nano-thin metal oxide layer(s).

In yet another aspect, the invention further provides improved terminal fly fishing tackle comprising a second coating layer positioned at least partially between the core and the metal oxide layer. A presently preferred embodiment for this particular two-layer coated terminal fishing tackle is as a fishing line or a fly. Such an improved fly fishing tackle will e.g. display improved protection against UV-light and chemical aggressions, and/or being super-hydrophilic.

In one aspect, the method for producing the improved terminal fly fishing tackle comprises using ALD technology. The fact that the at least partially metal oxide covered terminal tackle is produced using ALD technology, renders it possible to produce fibres and/or fabrics comprising thin layers of titanium oxide and/or aluminium oxide on their overall surface. Fibres and/or fabrics for use as terminal tackle, comprising such homogenous, substantially amorphous as well as pin-hole free layers of titanium oxide and/or aluminium oxide generated using ALD technology have not previously been described. Furthermore, these layers have been shown to be durable and not to break and/or flake off during a state-of-the-art use.

In a presently preferred embodiment, the method for producing the improved terminal fly fishing tackle comprises using ALD technology leads to at least partially metal oxide covered terminal tackle comprising thin layers of titanium oxide and aluminium oxide on their overall surface. Consequently, the present invention in this preferred aspect relates to fibres and/or fabrics for use as terminal tackle, comprising such homogenous, bi-layered and substantially amorphous and pin-hole free layers of titanium oxide and aluminium oxide.

### BRIEF DESCRIPTION OF THE DRAWINGS

FIG. 1: SEM image of fibres being coated with titanium oxide layer and bent at 180 degrees fifteen times. After the mechanical experiment no sign of flakes or detachment of in the coating layer was observed

FIG. 2: Partially coated fly which is partly submerged in water due to its hydrophobic and hydrophilic properties

FIG. 3: On the right, the fly fishing throwing line coated uncoated and right coated with TiO₂

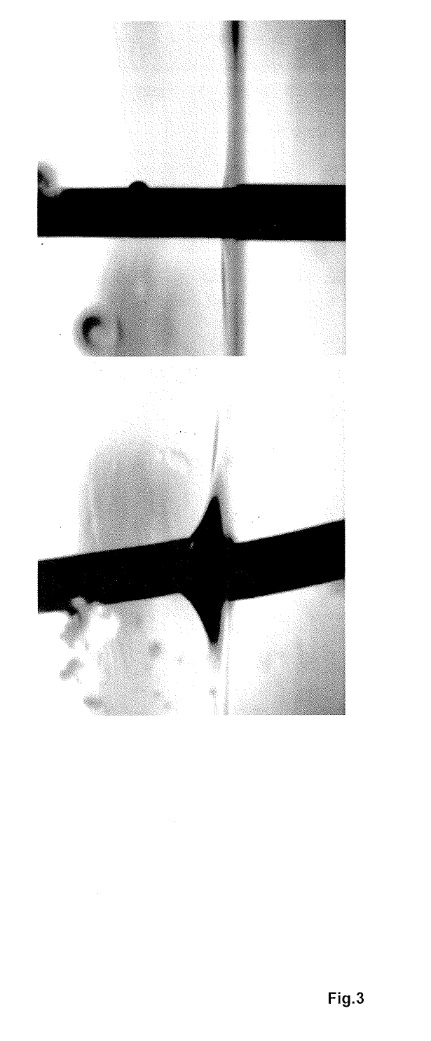

FIG. 4: On the right, fly coated with sputtered carbon, and on the left fly commercially available. The fly coated with carbon is still floating while the non-coated one already sank in the water

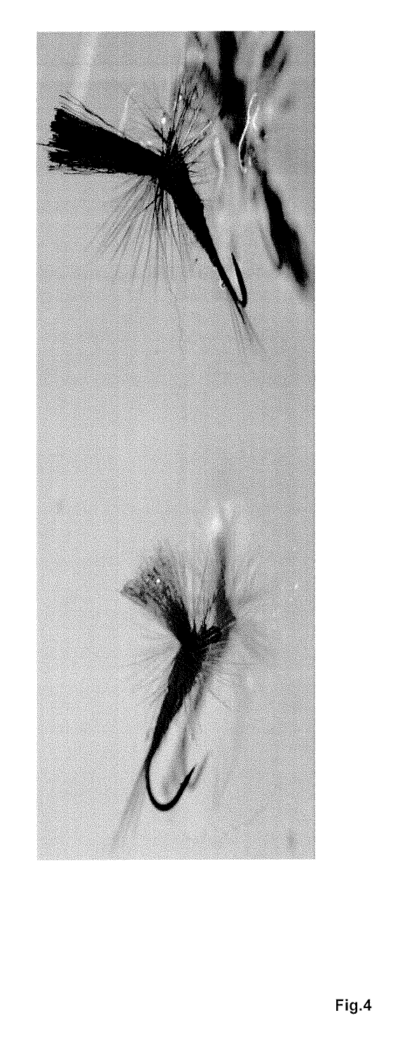

FIG. 5: SEM image of fibres being coated with Al₂O₃ layer and elongated 15%. After the mechanical experiments no sign of flakes or detachment of in the coating layer was observed, however some cracks were visible

FIG. 6: On the left, fly coated with Al₂O₃, and on the right fly commercially available. The fly coated with carbon shows higher resistance to water sorption than the non-coated one.

### DETAILED DESCRIPTION

In the present context, the term “terminal fishing tackle” or “terminal fly fishing tackle” includes, but is not limited to fishing lines, leaders, bait, lures, nymphs, tube-flies, streamers, zonkers, muddlers, salt-water flies, salmon flies, dry-flies and/or wet flies.

The use of the word “fly” is not intended to limit the invention to devices that simulate a fly. Other insects than flies and other creatures than insects are simulated and their simulation is still called a fly. This can include maggots, nymphs, tube flies, blobs, beetles, grasshoppers, bees, ants, larval stages of insects, insect larval cases, fish eggs, shrimp, frogs, mice, worms, spiders, brood, spawn, small fishes and other fresh and salt water creatures. When used in fly fishing, all of these artificial fish attractants are described as the “fly”.

By “fibres and/or fabrics” in the present context is meant a coated core material as disclosed herein that is to used for producing a fishing line, leader, bait, lure, nymph and/or fly.

By “coated” or “coating” is meant that a homogenous and substantially amorphous, pin hole free layer of metal oxide, in a presently preferred embodiment comprising predominantly titanium oxide and/or aluminium oxide, is placed, e.g. by using ALD technology as described herein, on a core material.

ALD technology (Atomic Layer Deposition) is a self-limiting, sequential surface chemistry method that deposits conformal thin-films of materials onto substrates of varying compositions. ALD film growth is self-limited and based on surface reactions, which makes achieving atomic scale deposition control possible. By keeping the precursors separate throughout the coating process, atomic layer control of film grown can be obtained as fine as ˜0.1 angstroms per monolayer. ALD grown films are conformal, pin-hole free, and chemically bonded to the substrate. With ALD it is possible to deposit coatings perfectly uniform in thickness inside deep trenches, porous media and around particles. The film thickness range provided by the ALD technology is usually 1-500 nm. When applying ALD technology on soft, pliant material, a substantially lower temperature than usual is used, typically in the range of lower than 300° C., such as lower than 275, 250, 220, 200, 175, 150, 125, 100, 90, 80, 70, 60, 50, 40, 30 or 20° C.

Unlike other coating techniques, ALD (atomic layer deposition) has the advantage of providing a pin hole free layer/film. In the present context the term “pin hole free layer/film” is used to describe that essentially the entire substrate is covered by the coating. ALD enables such coating in 3D structure essentially without holes in the layer/film. This is of major importance as, if the fishing fly is supposed to behave as intended, it is important that to all intents and purposes water can not penetrate the coating layer and soak the underlying material. Other coating techniques such as sputtering, CVD etc. are unable to provide such pin-hole free coatings. Tackle that is coated with any of these techniques will therefore not be effectively protected against diffusion of water into the underlying core material.

The term “homogenous” which in the present context is used to describe the characteristics of the metal oxide layer on the core material comprising the titanium oxide and/or aluminium oxide refers to a layer which is substantially uniform and even in its structure meaning that it has a thickness which is nearly constant over the whole layer which covers the core material. Of course there is always some variation in the structure of the layer, even though it may be described as homogenous.

In the present context, the term “amorphous” when discussed in the context of the metal oxide layer comprising titanium oxide, and7or aluminium oxide optionally in combination with one or more compounds, is meant to indicate that the relation of the atoms to each other is random, and stands interchangeably with non-crystalline atom structure. In the present context, a substantially amorphous metal oxide layer means that at least 50% of the atoms are present in a non-crystalline form, such as at least 51, 55, 60, 65, 70, 75, 80, 85, 90, 95, 97, 98, 99 or 100% of the atoms.

Especially preferred embodiments of the present invention relate to essentially “water-proof” or “water tight” fishing tackle, i.e. to objects that have been coated with a homogenous and substantially amorphous, pin hole free sealant layer of metal oxide that is essentially impermeable for water. The term “water-proof” is in the present context exchangeable with “water-resistant” or “water tight” and describes objects relatively unaffected by water or resisting water passage, i.e. which are covered or sealed with a layer that resists or does not allow water passage.

“Titanium oxide” in the present context covers e.g. TiO, Ti₂O₃, Ti₃O₅, and TiO₂

“Aluminium oxide” in the present context covers e.g. Al₂O₃, Sapphire, AlO(OH), and NaAl₁₁O₁₇

Photo-induced “super-hydrophilicity” is an important property of TiO₂ and good results have been reported for TiO₂₋ₓNₓ (R. Asahi, T. Morikawa, T. Ohwaki, K. Aoki and Y. Taga, Science 293 (2001), p. 269.).

Because of the need for light weight materials in the fly so that it can be whipped back and forth with the line and so that it will lay on the water without sinking like its natural counterpart would, flies are typically made using extremely light weight material such as animal hair, birds' feathers, and sometimes foam for wings. Other flies are designed to sink, and may even have weight attached to aid in sinking.

The use of hand-tied simulations of insects on a hook, used to catch fish has been well known for centuries, and thousands of patterns exist. Each pattern is made of a variety of materials and any particular pattern may specify hair or feathers taken from specific species of animals, as well as from a specific body part of those animals.

Several strategies in the design of fishing flies have evolved. One strategy is to make the artificial fly look and react as similar to a natural insect as possible. To achieve this, feathers, hair, plastic, various types of string, beads, lead strips, and other materials are tied to the hook to simulate a specific species of insects, including their wings, head, eyes, thorax, wing covers, legs and antennae. Other creatures in the fish's natural environment are also simulated using artificial flies. These include the eggs of fish, insects, insect larvae, larval cases, small mammals such as mice, shrimp, frogs, dragon flies, worms, minnows, bait fish, brood, spawn and crustaceans.

The terminal fly fish tackle described herein comprises a core material that can be made of synthetic material selected from the group consisting of polymer microspheres (PVC plastisol), glass microsphere, polyacrylonitrile (PAN), c is 1,4-poly butadiene (PBD), trans 1,4-poly butadiene (PBD), poly 1-butene (PB), polybutylene terephthalate (PBT), poly caprolactam (Nylon 6), polycarbonate (PC), polyamid (PA), poly 2,6-dimethyl-1,4-phenylene ether (PPE), poly ether ether ketone (PEEK), polyetherimide (PEI), polyethylene (PE)(LDPE)(MDPE)(HDPE)(UHMW), polyester, polyether, poly ethylene hexamethylene dicarbamate (PEND), polyethylene oxide (PEO), polyethylene sulphide (PES), polyethylene terephthalate (PET), polyhexamethylene adipamide (Nylon 6,6) (PHMA), polyhexamethylene sebacamide (Nylon 6,10) (PHMS), polyimide (PI), poly isobutylene (FIB), poly methyl methacrylate (PMMA), poly methyl pentene (PMP), poly m-methyl styrene (PMMS), poly p-methyl styrene (PPMS), poly oxymethylene (POM), poly pentamethylene hexamethylene dicarbamate (PPHD), poly m-phenylene isophthalamide (PMIA), poly phenylene oxide (PPO), poly p-phenylene sulphide (PPS), poly p-phenylene terephthalamide (PPTA), poly propylene (PP), poly propylene oxide (PPDX), polystyrene (PS), poly tetrafluoro ethylene (PTFE), poly urethane (PU), polyvinyl alcohol (PVA), polyvinyl chloride (PVC), polyvinyledene fluoride (PVDF), polyvinyl methyl ether (PVME), latex, actetate, carbon, polyaniline, polythiophene, polypyrrole, or a synthetic copolymer such as ABS plastic, SBR, Nitrile rubber, styrene-acrylonitrile, styrene-isoprene-styrene (SIS) and ethylene-vinyl acetate, polyurethane and polyethylene glycol (e.g. elastane, spandex, lycra, Elaspan).

In a preferred embodiment, the fish tackle described herein comprises a core material that is made of a synthetic material selected from the group consisting of polymer microspheres (PVC plastisol), glass microsphere, nylon monofilament (Polyamid, PA) nylon 6-6, nylon 5, 6, 10, polyethylene, Dacron and Dyneema (UHMWPE) copolymers or fluorocarbon (cofilament and thermally fused lines, also known as ‘superlines’ for their small diameter, lack of stretch, and great strength relative to standard nylon monofilament lines), polyethylene terephthalate (PET), polyester, polypropylene (PP), polyvinyl, acrylic fibers (comonomers are vinyl acetate or methyl acrylate), Polyurethane (PU), polyvinylchloride (PVC), polytetrafluoroethylene (PTFE), and polyacrylate.

Alternatively, or in combination with the above described synthetic materials, the fish tackle described herein can comprise a core material that is made of a natural material selected from the group consisting of satin, angora, alpaca wool, vicuña wool, llama wool, and camel hair, linen, rubber, silk, wool, rayon, cellulosic fibre, natural fibre, feather, animal skin and hair, velvet, or the plant textiles/biopolymers, bamboo, coir, flax, jute, kenaf, manila, piña, raffia, ramie, grass, rush, hemp, and sisal, fibres from pulpwood trees, cotton, rice, hemp, and nettle, viscose or a mineral textile, such as asbestos, basalt, mineral wool, and glass wool, or any combination thereof.

Furthermore, said core can comprise metallic wires and ribbons made from a metal preferably selected from the group consisting of gold, silver, copper, iron, aluminium, titanium, carbon, nickel, cobalt, zinc, vanadium, and lead, or any combination thereof.

Generally, it is greatly desirable to utilize a line while fly fishing that has a relatively low specific gravity. The lower the specific gravity, the higher the line floats since less water is displaced. Currently available fly fishing lines have specific gravities in the range of 0.85 to 0.95. Various fly fishing lines have coatings that typically are comprised of polyvinyl chloride polymer or urethane that include respectively glass microspheres or gaseous filled cells, dispersed throughout the coating to impart floatability by reducing the specific gravity to less than 1.00, usually somewhere between 0.85 and 0.90.

The present invention does not particularly aim at providing a fly fishing line with a decreased line density, but instead relates to lines and/or other terminal tackle that floats better due to its hydrophobic and/or super hydrophobic attributes or sinks better due to its hydrophilic and/or super hydrophilic attributes. The presently disclosed deposition technique is different from any previously used in the field as the coating layers are approximately up to 1000 times thinner than those known in the field of the art today. What is more, the techniques used herein provide uniform coatings on entire surface, as well as essentially pinhole free surfaces, whereas standard techniques use microsphere coatings with an average particle size of 35 to 55 microns.

In principle, the metal oxide to be used for the coating is selected according to its hydrophobicity (will stay above the water level) or hydrophilicity (will sink below the water level), depending on the suitable effect and the density of the coated material.

Since surface characteristics, such as hydrophobicity and hydrophobicity do not strictly depend on the thickness of the hydrophobic or hydrophilic metallic oxide composing the coating, a layer as thin as possible will prevent this coated layer from flaking of or cracking under usual mechanical loads. What is more, a layer thinner than 50 nm does not change the colour of the core material, since it is too thin to be optically visual.

Titanium oxide can have several colours depending on its thickness (doi:10.1016/S0040-6090(00)01542-X; Jiaguo Yu, Xiujian Zhao and Qingnan Zhao; Effect of surface structure on photocatalytic activity of TiO2 thin films prepared by sol-gel method. However, its photocatalytic, anti-microbial and/or anti-fouling properties are independent of the thickness (Quantitative Evaluation of the Photo induced Hydrophilic Conversion Properties of TiO2 Thin Film Surfaces by the Reciprocal of Contact Angle; Nobuyuki Sakai, Akira Fujishima, Toshiya Watanab and Kazuhito Hashimoto; J. Phys. Chem. B, 2003, 107 (4), pp 1028-1035 DOI: 10.1021/jp022105p Publication Date (Web): Jan. 1, 2003).

TiO2 in itself is slightly hydrophilic, and not hydrophobic. When exposed to UV light (i.e. direct sun light), the hydrophilicity increases dramatically due to the increase of the surface hydroxyl group (—OH) on the TiO₂ surface. When TiO₂ is not anymore exposed to UV light, it comes back to its original hydrophilicity, albeit slower than it took for it to become super hydrophilic.

So in fact, when the interface between water and coated terminal tackle is studied, the action of the layer (hydrophilicity and/or hydrophobicity) is independent of the coating thickness.

Another purpose of the nano-thin pin hole free coating of the present invention is its surface coverage ability to prevent the material supporting the coating from soaking water. In a presently preferred embodiment, at least one layer, preferably the layer closest to the core material and/or directly attaching to the core material is essentially a water impermeable, insoluble and waterproof sealant. Additional layers, with special surface characteristics, such as hydrophilicity and/or hydrophobicity can then optionally be applied on top of said first waterproof sealant layer.

Another advantage to prior art is, that it is almost impossible to see the coating by eyes, also, essentially no increase in diameter, essentially no increase in weight, and essentially no discoloring is immediately noticeable to the person skilled in the art.

The ALD coating is made in a close chamber, at high vacuum, at a temperature between 22 and 150 degrees. The metal oxide is deposed by successive atomic layers. Once the triggered thickness is reached, the process is stopped and the coated lines can be taken out.

Hence, in a first aspect, the present invention relates to a terminal tackle consisting of a coated core material, said coating comprising a homogenous, pin hole free and substantially amorphous metal oxide layer comprising in a preferred embodiment predominantly aluminium oxide and/or titanium oxide and having a thickness of 200 nm or less. In other embodiments, the thickness of said metal oxide layers is 100 nm or less, such as 100, 90, 80, 70, 60, 50, 40, 35, 30, 25, 20, 15, 10, 9, 8, 7, 5 or 2 nm or less. In other embodiments, the metal oxide layer has a thickness of between 0.04-200, 0.04-100, 0.04-50, 0.04-40, 0.04-25, 0.04-20, 0.04-15, 0.04-10, 0.04-5, 0.5-50, 0.5-25, 0.5-20, 0.5-15, 0.5-10, 0.5-5, 1-5, 1-10, 1-15, 1-20, or 1-25 nm, such as 0.5, 1, 2, 3, 4, 5, 6, 7, 8, 9, 10, 11, 12, 13, 14, 15, 16, 17, 18, 19, 20, 22 or 25 nm.

In the context of the present invention, the core material is selected from the group consisting of polyurethane (PUR, TPU, PCU), polyamid, (PA), polyether, polyethylene, (PE), polyester, polypropylene, (PP), poly(tetrafluoroethylene) (PTFE), silicones, cellulose and cotton.

In a presently preferred embodiment, the thickness of said metal oxide layer is less than 20 nm. In a more preferred embodiment, the thickness of said metal oxide layer is less than 10 nm. In an even more preferred embodiment, the thickness of said metal layer is less than 5 nm. In yet another preferred embodiment the metal oxide layer has a thickness which is less than 2 nm.

In the context of the present invention, said titanium oxide may be selected from the group consisting of TiO, Ti₂O₃, Ti₃O₅, and TiO₂.

In the context of the present invention, said aluminium oxide may be selected from the group consisting of Al₂O₃, Sapphire, AlO(OH), and NaAl₁₁O₁₇.

In a preferred aspect, the thickness of a metal oxide layer comprising in a preferred embodiment predominantly titanium oxide and/or aluminium oxide, optionally in combination with one or more compounds as defined herein, on a core material according to the present invention, is defined by a thickness which is such that it prevents that the metal oxide layer breaks and/or flakes off from the core material during slight bending and/or normal use thereof.

In preferred embodiments of the present invention, the terminal fishing tackle coating surface comprises at least 60% titanium oxide, such as at least 80, 90, 95 or 99% titanium oxide.

In preferred embodiments of the present invention, the terminal fishing tackle coating surface comprises at least 60% aluminium oxide, such as at least 80, 90, 95 or 99% aluminium oxide.

Preferably, the metal oxide layer comprising titanium oxide and/or aluminium oxide is amorphous, but occasionally, a minor percentage of the oxides can be present in a crystalline form, such as 49, 46, 40, 35, 30, 25, 20, 15, 10, 7, 5, 3, 1 or 0%

The presence of a metal oxide layer comprising predominantly titanium oxide and/or aluminium oxide on the terminal fishing tackle generates the possibility to reactivate the anti-microbial, anti-fouling, anti-viral and/or immunomodulatory activities of the fibres or fabrics by simple photo activation.

In one preferred aspect, the present invention relates to terminal fishing tackle, wherein said metal oxide layer of said coating additionally comprises one or more compound(s) selected from the group consisting of N, C, S, Cl, W, F, Si and/or one or more compounds selected from the group consisting of Cl, F and N, and/or one or more compounds selected from the group consisting of Ag, Au, Pd, Pt, Fe, Cl, F, Pb, Zn, Zr, B, Si, Br, Cr, Hg, Sr, Cu, I, Sn, Ta, W, Co, Mg, Mn, Si and Cd and/or one or more compounds selected from the group consisting of SnO₂, CaSnO₃, WO₃, FeGaO3, BaZrO₃, ZnO, Nb₂O₅, CdS, ZnO₂, SrBi₂O₅, BiAlVO₇, ZnInS₄, K6Nb_{10.8030}, Si₃N₄, SiC, SiH₄, SiF₂, Si₂O and/or a combination of compounds selected from said groups of compounds, wherein said one or more compound(s) selected from one or more group(s) of compounds are dispersed substantially homogenous within said metal oxide layer.

The addition to the metal oxide layer of one or more of the compounds selected from the group consisting of Cu, C, S, N, F and Cl has the effect that the photocatalytic properties of the metal oxide layer comprising predominantly titanium oxide may be varied. The reason for this is that these compounds have the ability of changing the wavelength at which the light is absorbed by the metal oxide layer, allowing for different light sources to be used in the activation and/or boosting of the photocatalytic properties of the metal oxide layer of the fibres or fabrics. Hence, in view thereof, not only UV light, but also visible light as well as can be used for this purpose.

Further, the group consisting of Cl, F and N, as well as the group of inorganic compounds consisting of SnO₂, CaSnO₃, WO₃, FeGaO₃, BaZrO₃, ZnO, Nb₂O₅, CdS, ZnO₂, SrBi₂O₅, BiAlVO₇, ZnInS₄, K6Nb_{10.8030}, provides enhanced photocatalytic properties to the terminal fishing tackle.

In one embodiment, the metal oxide layer comprising predominantly titanium oxide of the fibres or fabrics according to the present invention comprises about 100% titanium oxide.

In one embodiment, the metal oxide layer comprising predominantly aluminium oxide of the fibres or fabrics according to the present invention comprises about 100% aluminium oxide.

In other embodiments, the proportion of titanium oxide and/or aluminium oxide present in said metal oxide layer, when combined with one or more compounds selected from the group consisting of Si, N, C, F, S, Cl, and/or one or more compounds selected from the group consisting of Cl, F, Si and N, and/or one or more compounds selected from the group consisting of Ag, Au, Pd, Pt, Fe, Cl, F, Pb, Zn, Zr, B, Br, Cr, Si, Hg, Sr, Cu, I, Sn, Ta, W, Co, Mg, Mn, Si and Cd, or an oxide thereof and/or one or more compounds selected from the group consisting of SnO₂, CaSnO₃, WO₃, FeGaO₃, BaZrO₃, ZnO, Nb₂O₅, CdS, ZnO₂, SrBi₂O₅, BiAlVO₇, ZnInS₄, K6Nb_{10.8030}, Si₃N₄, SIC, SiH₄, SiF₂, Si₂O and/or a combination of compounds selected from said groups of compounds, is between about 1-99% of said metal oxide layer, such as about 5, 10, 20, 30, 40, 50, 60, 70, 80, 90, 95, 97, 98 or 99% of said metal oxide layer.

In a presently preferred embodiment, titanium oxide and/or aluminium oxide are combined with Cu, Zn and/or Ag, wherein equally preferred embodiments is titanium oxide and/or aluminium oxide combined with e.g. C, N, S, Au, Pd, Pt, Fe, Cl, F, Pb, Zr, B, Br, Si, Cr, Hg, Sr, Cu, I, Sn, Ta, W, Co, Mg, Mn, and Cd.

In other aspect of the present invention, an oxide of any of the metals disclosed above is added to the metal oxide layer according to the present invention. Hence, added to the metal oxide layer on the terminal fishing tackle, according to the present invention, may be Ag or an oxide thereof, Zn or an oxide thereof, Zr or an oxide thereof, Co or an oxide thereof, Pt or an oxide thereof, Si or an oxide thereof, Mg or an oxide thereof, Mn or an oxide thereof, Sr or an oxide thereof, W or an oxide thereof, Ta or an oxide thereof, Cu or an oxide thereof, Au or an oxide thereof, Fe or an oxide thereof, Pd or an oxide thereof, Hg or an oxide thereof, Sn or an oxide thereof, B or an oxide thereof, Br or an oxide thereof, Cd or an oxide thereof, Cr or an oxide thereof, Cl or a chloride containing compound (not oxide, see below also), Sr or an oxide thereof, F or a fluoride/fluorine containing compound, I or a iodide containing compound, N or an oxide thereof, S or an oxide thereof, C or a carbide containing compound, but is not limited thereto.

In a presently preferred embodiment, titanium oxide and/or aluminium oxide is combined with Zn in a metal oxide layer according to the present invention. In such combination, it is presently preferred that the proportions of the other compounds mentioned herein and titanium oxide and/or aluminium oxide are respectively and approximately 1/99, 2/98, 3/97, 4/96, 5/95, 6/94, 7/93, 8/92, 9/91, 10/90, 20/80, 30/70, 40/60 or 50/50

In another aspect, the present invention relates to a method for reactivating and/or boosting the photo catalytic properties of a terminal fishing tackle according to the invention, by applying photo activation with high energy light or visible light to said metal oxide layer of said core material. In one embodiment said high energy light is sunlight, UV light, blue light and/or laser light.

In another aspect, the present invention relates to method for producing a terminal fishing tackle according to the present invention, which has improved photo catalytic and anti-microbiological properties, said method comprising the steps of selecting a core material, adding said metal oxide layer onto said core material and optionally, simultaneously adding one or more compounds selected from the group consisting of N, C, F, S, Cl, and/or one or more compounds selected from the group consisting of Cl, F, and N, and/or one or more compounds selected from the group consisting of Ag, Au, Pd, Pt, Fe, Cl, F, Pb, Zn, Zr, B, Br, Cr, Hg, Si, Sr, Cu, I, Sn, Ta, W, Co, Mg, Mn and Cd and/or one or more compounds selected from the group consisting of SnO₂, CaSnO₃, FeGaO₃, BaZrO₃, ZnO, Nb₂O₅, CdS, ZnO₂, SrBi₂O₅, BiAlVO₇, ZnInS₄, K6Nb_{10.8030}, Si₃N₄, SIC, SiH₄, SiF₂, Si₂O and/or a combination of compounds selected from said groups of compounds, to said metal oxide layer; said one or more compound(s) being dispersed substantially homogenous within said metal oxide layer. In one embodiment, said one or more compounds are added to the metal oxide layer by co-pulsing and/or mixing said compounds into said metal oxide layer. Pulsing is defined as alternating the injections of reactive products into the ALD reactor.

In a preferred embodiment of the present invention, said terminal fishing tackle is produced using ALD (Atomic Layer Deposition) technology for attaching said metal oxide layer onto said core material, and/or onto said assembled terminal tackle. In a preferred embodiment, said ALD reaction is performed at a reaction temperature of about 20-500° C., such as between 20-400° C., 20-300° C., 20-200° C., 20-100° C., 50-300° C., 50-200° C. or 50-150° C. or 80-200° C. In a more preferred embodiment, said temperature is about 80-150° C. In a yet more preferred embodiment, approximately 80-120° C. is used for the reaction conditions.

The selection of temperature will affect the structure of the metal oxide layer comprising the titanium oxide which is formed, i.e. the higher temperature employed, the higher percentage of crystalline structures will be obtained. For example for TiO₂, temperatures above about 160° C. will increase the crystalline part of the material. By adding Cl or F to the metal oxide layer, this transition temperature will be lowered.

In general, the metal oxide layer coating can either be applied onto the raw core material, onto a pre-coated core material, and/or onto the assembled terminal fishing tackle, which can of course be pre-coated as well. The coating can be achieved in a single sitting, or be performed repeatedly. Also, terminal fishing tackle can be re-coated, should the desired effect of the coating not be satisfactory, or wear off over time and/or repeated and/or harsh handling. What is more, it can be desirable to coat parts of the terminal fishing tackle with different coatings, and or to coat only parts of the terminal fishing tackle, leaving other parts uncoated. The presently disclosed methods provide the means to vary the coating accordingly.

ALD technology has previously mainly been used to deposit metal oxide layers onto solid materials such as silica, MgO and soda lime glass. Surprisingly, the present inventors have now for the first time by using ALD technology been able to produce terminal fishing tackle, consisting of an at least partially coated material, wherein said coating comprises a homogenous and substantially amorphous metal oxide layer in a preferred embodiment comprising predominantly titanium oxide and or aluminium oxide. Hence, the new technique using ALD provides a terminal fishing tackle with a nano-coating of a metal oxide, as disclosed herein, which allows for manipulation and use of said terminal fishing tackle without damaging the metal oxide layer thereon, which would allow the metal oxide(s) to break and/or flake off there from. The latter has been a recognized problem in the art, as the layers of metal oxide which have been deposited have been too thick, causing the metal oxide layer to break and also to flake. This is due to the fact that the techniques used so far have not been sensitive enough to be able to provide such thin layers thereby avoiding these events.

The use of ALD to provide a nanoscale coating according to the present invention makes it possible to produce durable and pin hole free nano-thin metal oxide layers, or nano-composites, on a plethora of fibres and/or fabrics, which maintain their characteristics throughout the use. Doping the materials with specific atoms, the photo catalytic effect can be improved at specific wavelengths providing a method for further increasing the efficacy and effectiveness of the photo catalytic coating. Further, the applications of said nano-layer coatings and nano-composite layers surprisingly do not affect the mechanical properties of the substrate (pliability, flexibility, elasticity etc.) but rather enhances and reinforces the strength, durability and stability of said materials.

In the context of the present invention, said terminal fishing tackle consisting of a coated core material, said coating comprising a homogenous, pin hole free and substantially amorphous metal oxide layer comprising predominantly titanium oxide, provides anti-fouling and/or anti-microbiological properties due to the photocatalytic properties of said metal oxide layer and optionally also via the additional compounds added to the metal oxide layer, which has further been explained herein. In one embodiment, the anti-fouling and/or anti-bacterial properties of said nano-thin layer present on said core material is reactivated and/or boosted by applying photo activation with high energy light or visible light to said metal oxide layer. Said high energy light may be selected from, but is not limited to, sunlight, UV light, blue light or laser light. High energy light is often defined as light with wavelength lower than 385 nm.

In yet another aspect, the present invention is related to a terminal fishing tackle, wherein the metal oxide nano-layers present thereon provides a mechanical nano-composite coating that reinforces the mechanical properties of the material, makes a waterproof sealant, provides anti-fouling properties to said terminal fishing tackle, thereby avoiding and prohibiting the accumulation and deposition of unwanted organic material thereon, and modifies the surface charge. It is also encompassed by the present invention, that the anti-fouling properties of said metal oxide layer present on said terminal fishing tackle are reactivated and/or boosted by applying photo activation with high energy light or visible light to said core material. Said high energy light may be selected from, but it not limited to sunlight, UV light, blue light or laser light.

### Experimental Section

### Example 1

### Hydrophilic Coating of a Wet Fly

TiClₐ and H₂O were used to coat the fly-fishing fly, which is supposed to sink, e.g. a salmon fly, with TiO₂. Films were grown in a commercial F-120 Sat reactor (ASM Microchemistry) by using TiCl₄ (Fluka; 98%) and H₂O (distilled) as precursors. Both precursors were kept at room temperature in vessels outside the reactor during the deposition. The reactor pressure was maintained at ca. 1.8 mbar by employing an N₂ carrier-gas flow of 300 cm³ min⁻¹ supplied from a Nitrox 3001 nitrogen purifier with a purity of 99.9995% inert gas (N₂+Ar) according to specifications.

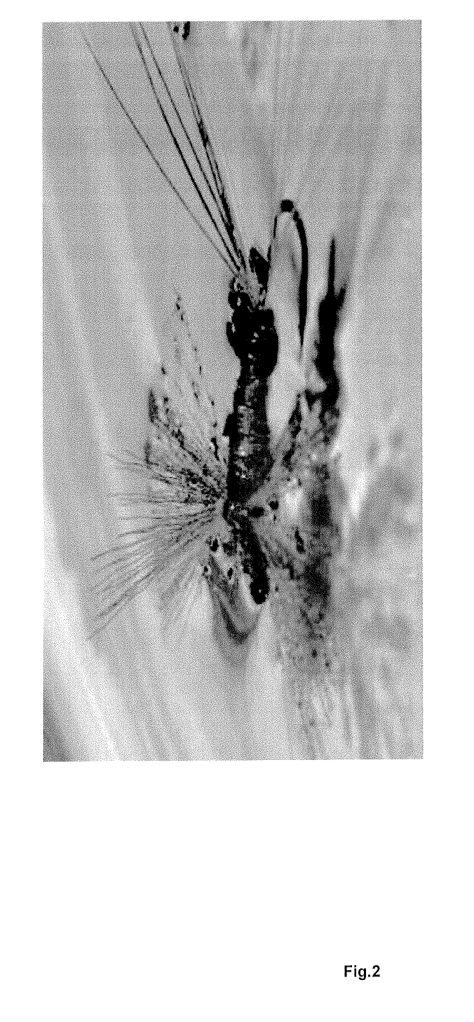

The films were grown using a pulsing scheme of 2 s pulse of TiCl₄ followed by a purge of 1 s. Water was then admitted using a pulse of 2 s followed by a purge of 1 s. This complete pulsing scheme makes up one pulsing cycle and the films were made using different numbers of such cycles (typically from 20-2000 cycles). Films can be formed in a relatively large temperature interval as shown in FIG. 2. Using a deposition temperature of 120° C. a growth rate of 0.046 nm/cycle was obtained. Thus the coating procedure used 200 cycles, which gave a titanium oxide thickness of <10 nm.

The deposition may be expressed accordingly:

TiCl₄(g)+—OH→|—O—TiCl₃+HCl(g) Step 1:

|—O—TiCl₃+H₂O(g)→|—O—Ti—(OH)₃+3HCl(g) Step 2:

The reactions may be shifted so that the liberation of HCl(g) is more in step 1 and less in step 2 depending on the reaction conditions. See R. L. Puurunen, J. Appl. Phys. 97 (2005) 121301.

By performing the deposition at a reactor temperature at or below 165° C., the resulting layer may be practically amorphous. The amorphous film may optionally be converted into the TiO₂ forms rutile or anatase by post annealing. Alternatively, the structure may be controlled in situ as described in J. Aarik et al., J. Cryst. Growth 148: 268 (1995) where anatase is deposited in the range 165-350° C. and rutile is obtained at temperatures above 350° C.

The surface was examined in a blue light profilometer (PLU 2300, Sensofar, Spain) and a set of roughness parameters were quantified (n=5). The result is displayed in Table 1. The surface is smooth since the Sa is 243 nm and Sq (root mean square) 226 nm.

Table 1: Roughness parameters from blue light Profilometer of a titanium oxide (Sa=roughness average, Sq=Root-Mean-Square (RMS) deviation of the surface. Computes the efficient value for the amplitudes of the surface (RMS), Sp=Maximum height of summits, height between the highest peak and the mean plane, Sv=Maximum depth of valleys, depth between the mean plane and the deepest valley, St=Total height of the surface, height between the highest peak and the deepest hole, Ssk=Skewness of the height distribution. A negative Ssk indicates that the surface is composed with principally one plateau and deep and fine valleys. In this case, the distribution is sloping to the top. A positive Ssk indicates a surface with lots of peaks on a plane. The distribution is sloping to the bottom. Due to the big exponent used, this is very sensitive to the sampling and to the noise of the measurement. Sku=Kurtosis of the height distribution, Sku>3=summits very steep. Positive, sharp peaks, negative, flat peaks. Due to the big exponent used, this is very sensitive to the sampling and to the noise of the measurement. Sz=Ten Point Height of the surface, calculated by the mean Szi on zones with a width equal to the auto-correlation length of the surface, Smmr=Mean material volume ratio.).

TABLE 1

| Parameter | Sa | Sci | Sq | Sp | Sv | Sskw | Ssk | Sku | Sz | Smmr |
|---|---|---|---|---|---|---|---|---|---|---|
| Unit | μm | — | μm | μm | μm | — | — | — | μm | μm3/μm2 |
| Mean | 0.243 | 1.572 | 0.226 | 1.135 | 0.825 | 0.643 | 0.670 | 6.805 | 1.100 | 0.890 |

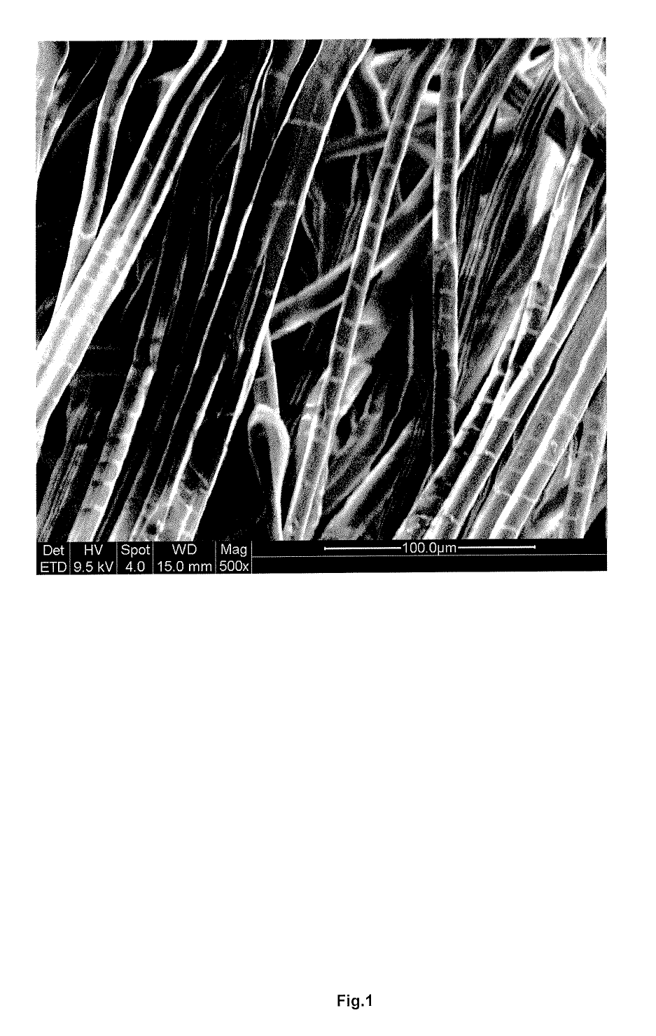

The resulting layer of titanium oxide layer did not affect the pliability or appearance of the material. Experiments on the mechanical properties performed were stretching and bending of the material. 1) Bending 45 degrees, 2) Bending 60 degrees, 3) Bending 90 degrees 4) Bending 180 degrees, 5) Consecutive bending at 180 degrees fifteen times. After the mechanical experiment no sign of flakes or detachment of in the coating layer was observed even when examined at high magnification in a scanning electron microscope. Moreover, the deposition of TiO₂ as illustrated by the smooth appearance mechanical stability of the photocatalyst layer visualized in the SEM after mechanical stress testing (FIG. 1).

### Example 2

A salmon fly-fishing fly was coated as described as example 1. The contact angle was subsequently measured with a static water contact angle machine (SCA20, DataPhysics GmBH, Germany) and was significantly reduced when compared to a uncoated salmon fly

### Example 3

A salmon fly-fishing fly was coated as described as in example 1. After 5, 10, 15 and 20 minutes exposure in UV light (4 W/m2, wavelength 270 nm), a water drop was placed on top the surface of the fibers and the body of the fly. The contact angle was subsequently measured with a static water contact angle machine (SCA20, DataPhysics GmBH, Germany). The contact angle was measured after the time intervals 5, 10, 15 and 20 minutes and the contact angle dropped from 100°, to 80° to 60° and at last 30° with the given exposure time. After 20 minutes of exposure the fly became super hydrophilic.

### Example 4

A fly imitating a fly nymph was partially coated, where the body was coated as described in example 1 and the wings were left uncoated. In the figure below one can see that the body and the hook is submerged in water, where as the uncoated part remains floating see FIG. 2)

### Example 5

A fishing line was coated with the same manner as described in example 1

### Example 6

The fishing line (leader) described in example 5 underwent a contact angle measurement. The images of the fishing line with coating show that the meniscus of the water decreased when the TiO2 layer was deposited, which means that the line with a TiO2 coating is more hydrophilic (FIG. 1). This property for the leader would make it more invisible when fishing.

### Example 7

A fly-fishing fly where coated as described in example 1. This fly was used for fishing for two days, and absorbed various kind of organic debris and fouling. The fly was placed under UV-light for 15 minutes (4 W/m2, wavelength 250 nm). All the organic substances degraded and proved that the TiO2 coating has a self-cleaning effect.

### Example 8

A layer of Al₂O₃ was deposited on a commercially available fly using the ALD (atomic layer deposition) technique in a F-120 Sat reactor (ASM Microchemistry) (FIG. 1). The deposition was performed using Al(CH₃)₃ (trimethylaluminium, TMA) (Witco) and O₃ as precursors at a deposition temperature of 100° C. The TMA precursor was used at room temperature while the O₃ precursor was delivered from an OT-020 ozone generator provided with 99.999% O₂ (AGA) at a rate of 500 sccm. A thickness of 5 nm was reached after 51 deposition cycles.

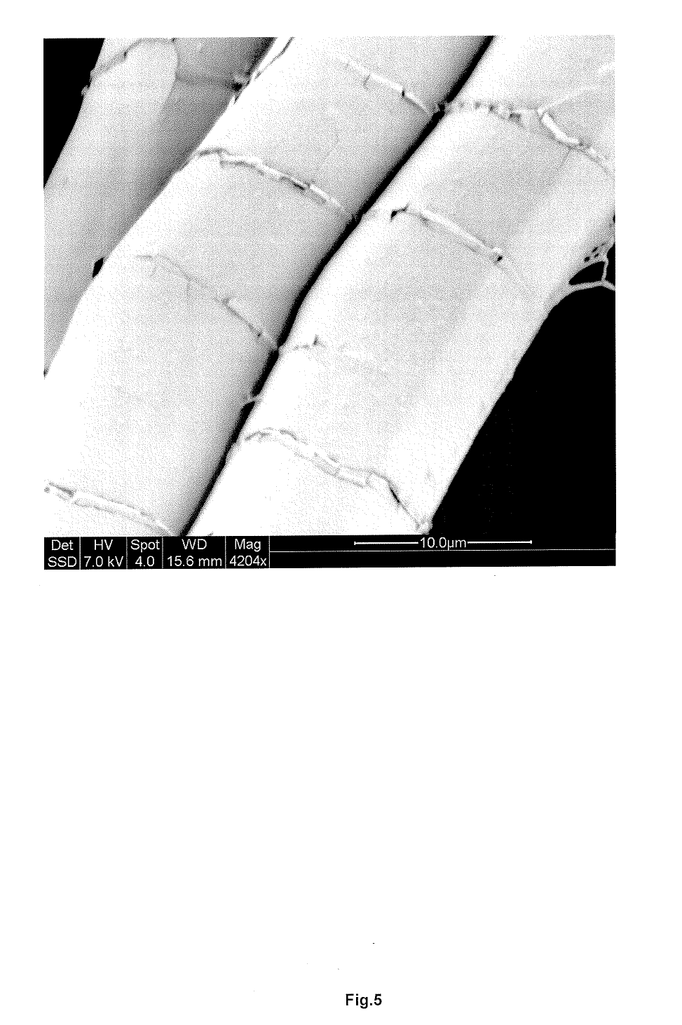

The resulting layer of Al₂O₃ did not affect the pliability or appearance of the material. Experiments on the mechanical properties of the following sequencing 1) Bending 45 degrees, 2) Bending 60 degrees, 3) Bending 90 degrees 4) Bending 180 degrees, 5) Consecutive bending at 180 degrees fifty times, 6) Elongation (stretching) of material up to 15%. (FIG. 5) showed that the layer is firmly attached to the substrate and that it did not flaked off after the six different testing modes, even when examined at high magnification in a scanning electron microscope.

### Example 9

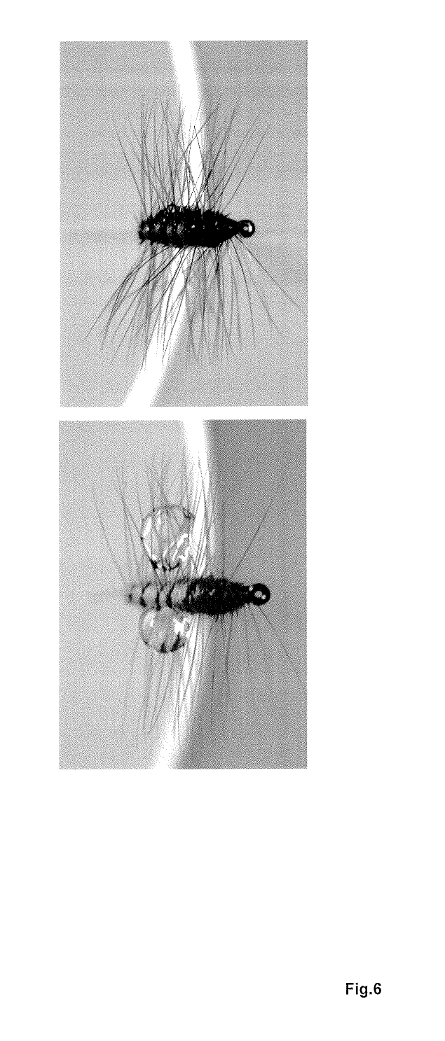

Two commercially available fly were compared, whereas the first had coating as described in example 9 and the other was uncoated. Both fly had two drop of sterile water of 5 μL place on both wings. The water drops remained on the wings for the coated fly, whereas the uncoated one absorbed the two water drop (see FIG. 6)

### Example 10

Two commercially available fly were compared, whereas the first had coating as described in example 9 and the other was uncoated. These two flies where placed under water for 5 minutes. Subsequently, the flies where shaken three times and let to dry at room temperature. The coated fly dried within 2 minutes, whereas the uncoated fly was still wet after 30 minutes

### Example 11

A fishing line was coated as described in example 9 and placed on water and compared with an uncoated line. The coated line floated significantly better than the uncoated one (FIG. 5)

### Example 12

TiOₓN_{y} surfaces may be produced by varying the usage of H₂O and NH₃ as precursor in the reaction scheme described for growth of TiO₂ by the means of co-pulsing. The doping took place on a polymeric fiber. The reaction scheme may be as follows:

TiCl₄(g)+|—OH→|—O—TiCl₃+HCl(g) Step 1:

|—O—TiCl₃+3H₂O(g)→|—O—Ti—OH)₃+3HCl(g) Step 2a:

|—O—TiCl₃+3NH₃(g)—|—O—Ti—(NH₂)₃+3HCl(g) Step 2b:

Photocatalytic degradation measurements were performed on a solid layer of stearic acid (CH₃(CH₂)₁₆CO₂H, Aldrich, 95%). UV illumination was done with a dental UV lamp that emits at wavelengths 340-410 nm with a peak maximum at 365 nm. The change in steric acid layer thickness was monitored by measuring infrared absorption spectrum in a transmission mode by Perkin-Elmer Spectrum FTIRI instrument (Spotlight 400, Perkin Elmer, Norway). Films 1 and 2 absorbed significantly more visible light. With samples 1-5 the photocatalytic activity decreases with increasing nitrogen concentration. Nitrogen doping by the present method can thus be regarded as detrimental to photocatalytic activity. ALD can be used in the preparation of nitrogen-doped TiO2 films which are excited by visible light (>380 nm).

Photo-induced super-hydrophilicity is an important property of TiO₂ and good results have been reported for TiO₂₋ₓNₓ (R. Asahi, T. Morikawa, T. Ohwaki, K. Aoki and Y. Taga, Science 293 (2001), p. 269.). The wetting properties of the films were studied by measuring their contact angles with water as a function of UV or visible light irradiation.

None of the samples became super-hydrophilic (contact angle below 10°) when visible light was used for irradiation. However, when UV light was used some samples did show super-hydrophilic behaviour.

### Example 13

### Titanium Oxide Doped with Nitrogen

Beaver fibers were coated with a doped titanium oxide surface. This was performed by ALD (Atomic Layer Deposition). Films were grown in a commercial F-120 Sat reactor (ASM Microchemistry) by using TiCl₄ (Fluka; 98%), NH₃ (Fluka; 99%) and H₂O (distilled) as precursors. Both precursors were kept at room temperature in vessels outside the reactor during the deposition. The reactor pressure was maintained at ca. 1.8 mbar by employing an N₂ carrier-gas flow of 300 cm³ min⁻¹ supplied from a Nitrox 3001 nitrogen purifier with a purity of 99.9995% inert gas (N₂+Ar) according to specifications. The doping of the titanium oxide layer was performed by alternating the pulsing of TiCl₄(g) and H₂O(g) separated by pulses of an ammonia gas as mentioned above.

One alternative process is:

Ti(Oi-Pr)_{4(g)}+NH_{3(g)}=TiOₓN_{y(s)}+H-i-Pr_{(g)} (1)

where i-Pr is isopropyl, and x and y are arbitrary numbers.

This complete pulsing scheme makes up one pulsing cycle and the films were made using different numbers of such cycles (typically from 20-2000 cycles).

### Example 14

### Titanium Oxide Doped with Sulphide

Polyamid fibers were coated with titanium oxide doped sulphide surface. This was performed by ALD (Atomic Layer Deposition). Films were grown in a commercial F-120 Sat reactor (ASM Microchemistry) by using TiCl₄ (Fluka; 98%), S (Fluka; 99%) and H₂O (distilled) as precursors. Both precursors were kept at room temperature in vessels outside the reactor during the deposition. The reactor pressure was maintained at ca. 1.8 mbar by employing an N₂ carrier-gas flow of 500 cm³ min⁻¹ supplied from a Nitrox 3001 nitrogen purifier with a purity of 99.9995% inert gas (N₂+Ar) according to specifications. The doping of the titanium oxide layer was performed by alternating the pulsing of Ti(Oi-Pr)₄(g) and H₂O(g) separated by pulses of hydrogen sulphide gas. The alternative process which occurs is:

Ti(Oi-Pr)_{4(g)}+H₂S_{(g)}=TiOₓS_{y(s)}+H-i-Pr_{(g)} (1)

where i-Pr is isopropyl, and x and y are arbitrary numbers.

This complete pulsing scheme makes up one pulsing cycle and the films were made using different numbers of such cycles (typically from 20-2000 cycles).

### Example 15

### Titanium Oxide Doped with Chlorine

Poly(tetrafluoroethylene) (PTFE) fibers were coated with titanium oxide doped with fluorine surface. This was performed by ALD (Atomic Layer Deposition). Films were grown in a commercial F-120 Sat reactor (ASM Microchemistry) by using TiCl₄ (Fluka; 98%), Cl₂ (Fluka; 99%) and H₂O (distilled) as precursors. Both precursors were kept at room temperature in vessels outside the reactor during the deposition. The reactor pressure was maintained at ca. 1.8 mbar by employing an N₂ carrier-gas flow of 300 cm³ min⁻¹ supplied from a Nitrox 3001 nitrogen purifier with a purity of 99.9995% inert gas (N₂+Ar) according to specifications. The doping of the titanium oxide layer was performed by alternating the pulsing of TiCl₄(g) and H₂O(g) separated by pulses of an chloridric gas. The alternative process which occurs is:

Ti(Oi-Pr)_{4(g)}+Cl_{2(g)}=TiOₓCl_{y(s)}+H-i-Pr_{(g)} (1)

where i-Pr is isopropyl, and x and y are arbitrary numbers.

This complete pulsing scheme makes up one pulsing cycle and the films were made using different numbers of such cycles (typically from 20-2000 cycles).

### Example 16

### Titanium Oxide Doped with Magnesium Oxide

Silk fibers were coated with titanium oxide doped with magnesium oxide surface. This was performed by ALD (Atomic Layer Deposition). Films were grown in a commercial F-120 Sat reactor (ASM Microchemistry) by using TiCl₄ (Fluka; 98%), MgCp₂ (g) (Fluka, 99%), H₂O (Fluka; 99%) and H₂O (distilled) as precursors. Both precursors were kept at room temperature in vessels outside the reactor during the deposition. The reactor pressure was maintained at ca. 1.8 mbar by employing an N₂ carrier-gas flow of 500 cm³ min⁻¹ supplied from a Nitrox 3001 nitrogen purifier with a purity of 99.9995% inert gas (N₂+Ar) according to specifications. The doping of the titanium oxide layer was performed by adding some alternating the pulsing of MgCp₂ (g) and H₂O (g) into the procedure for depositing TiO₂.

The complete pulsing scheme makes up one pulsing cycle and the films were made using different numbers of such cycles (typically from 20-2000 cycles).

### Example 17

### Titanium Oxide Doped with Manganese Oxide

Poly(tetrafluoroethylene) (PTFE) fibers with coated titanium oxide doped with MANGANESE OXIDE. This was performed by ALD (Atomic Layer Deposition). Films were grown in a commercial F-120 Sat reactor (ASM Microchemistry) by using TiCl₄ (Fluka; 98%), Mn(thd)₃ (g) (Fluka, 99%), O₃ (Fluka; 99%) and H₂O (distilled) as precursors. Both precursors were kept at room temperature in vessels outside the reactor during the deposition. The reactor pressure was maintained at ca. 1.8 mbar by employing an N₂ carrier-gas flow of 500 cm³ min⁻¹ supplied from a Nitrox 3001 nitrogen purifier with a purity of 99.9995% inert gas (N₂+Ar) according to specifications. The doping of the titanium oxide layer was performed by adding alternating pulsing of Mn(thd)₃ (g) and O₃ (g) to the process of deposition of TiO₂.

The complete pulsing scheme makes up one pulsing cycle and the films were made using different numbers of such cycles (typically from 20-2000 cycles).

### Example 18

### Titanium Oxide Doped with Silicon

A salmon fly was coated with titanium oxide doped with silicone. This was performed by ALD (Atomic Layer Deposition). Films were grown in a commercial F-120 Sat reactor (ASM Microchemistry) by using TiCl₄ (Fluka; 98%), SiCl₂H₂ (g) (Fluka, 99%), H2 (Fluka; 99%) and H₂O (distilled) as precursors. Both precursors were kept at room temperature in vessels outside the reactor during the deposition. The reactor pressure was maintained at ca. 1.8 mbar by employing an N₂ carrier-gas flow of 500 cm³ min⁻¹ supplied from a Nitrox 3001 nitrogen purifier with a purity of 99.9995% inert gas (N₂+Ar) according to specifications. The doping of the titanium oxide layer was performed addition of alternating pulsing of SiCl₂H₂ (g) and H₂O (g). In order to catalyze the growth of SlO₂ from SiCl₂H₂ and H₂O, some pyridine was added to the SiCl₂H₂ pulses.

The complete pulsing scheme makes up one pulsing cycle and the films were made using different numbers of such cycles (typically from 20-2000 cycles).

### Example 19

### Titanium Oxide Doped with Chromium Oxide

Polyester fibres were coated with titanium oxide doped with chromium oxide. This was performed by ALD (Atomic Layer Deposition). Films were grown in a commercial F-120 Sat reactor (ASM Microchemistry) by using TiCl₄ (Fluka; 98%), Cr(thd)₃ (g) (Fluka, 99%), O₃ (Fluka; 99%) and H₂O (distilled) as precursors. Both precursors were kept at room temperature in vessels outside the reactor during the deposition. The reactor pressure was maintained at ca. 1.8 mbar by employing an N₂ carrier-gas flow of 300 cm³ min⁻¹ supplied from a Nitrox 3001 nitrogen purifier with a purity of 99.9995% inert gas (N₂+Ar) according to specifications. The doping of the titanium oxide layer was performed by alternating the pulsing of Cr(thd)₃ (g) and O₃ (g).

The complete pulsing scheme makes up one pulsing cycle and the films were made using different numbers of such cycles (typically from 20-2000 cycles).

### Example 20

### Titanium Oxide Doped with Cobalt

Polyether fibers were coated with titanium oxide doped with cobalt. This was performed by ALD (Atomic Layer Deposition). Films were grown in a commercial F-120 Sat reactor (ASM Microchemistry) by using TiCl₄ (Fluka; 98%), Co(thd)₂ (g) (Fluka, 99%), O₃ (Fluka; 99%) and H₂O (distilled) as precursors. Both precursors were kept at room temperature in vessels outside the reactor during the deposition. The reactor pressure was maintained at ca. 1.8 mbar by employing an N₂ carrier-gas flow of 300 cm³ min⁻¹ supplied from a Nitrox 3001 nitrogen purifier with a purity of 99.9995% inert gas (N₂+Ar) according to specifications. The doping of the titanium oxide layer was performed by alternating the pulsing of Co(thd)₂ (g) and O₃ (g).

The complete pulsing scheme makes up one pulsing cycle and the films were made using different numbers of such cycles (typically from 20-2000 cycles).

### Example 21

### Hydrophobic and Waterproof Dry Flies

The aim of the experiment was to provide a permanent nano-coating for dry flies, which is water tight and water repellent, and therefore keeps the dry fly perpetually floating even after forced submerging.

In the current experiment 4 groups of identical dry flies (May fly no. 10, Midgarflyfish.com AS, Oslo, Norway); 1) untreated, 2) coated with silicone oil (commercial gold standard, Fly Floatant®, Scientific Anglers Ltd), 3) sputter coating (108 Carbon A, Chressington Carbon Coater) with carbon (0.001 mbar, 40 mA, 30 sec) and 4) ALD coating with a composite layer consisting starting with 20 nm aluminum oxide (Al₂O₃), 5 nm TiO₂, 5 nm Al₂O₃, 5 nm TiO₂, 5 nm Al₂O₃, 5 nm TiO₂, and ending with 15 nm Al₂O₃ (total 60 nm of coating) at low temperature (<100 C), where tested.

The flies were weighted with a high precision balance ( 1/1000 g), dipped in water for several times with vigorous stirring, then dried by blowing strongly 5 times, and finally weighted again. By this mean, the intake of water of the flies when dragged under water could be measured in order to determine if the treatment increased their waterproof ability, increase in weight, floating time and Max number of forced submerging before sinking. Static contact angle was measure with ultrapure water (OCA 20, Digital Physic GmbH, Germany). The result is displayed in table 2.

TABLE 2
Result from water uptake study

| | | | | Max number |
|---|---|---|---|---|
| | | Contact | Floating time | of forced |
| | Increase in | angle | after 1 | submering |
| Treatment | weight (%) | (degrees) | submerging | before sinking |
| Non-treated | 74 | 103 | <1 min | 1 |
| coated with Fly | 62 | 140 | 32 min | 5 |
| Flotant ® | | | | |
| Sputter coated | 68 | 112 | 14 min | 4 |
| carbon | | | | |
| ALD sandwich | 27 | 145 | More than 4 | >50 |
| later | | | days | |

Conclusion: The non-treated fly absorbed water and sunk quickly and was difficult to dry, as expected. The sputter coating did not provide a 3D and pin hole free film suitable for dry flies, as this film did not provide a completely water tight layer. The flies coated with commercial Flyflotant® performed according to manufacturing specifications, however due to solubility of the coating, the effect wore off within half an hour. The ALD composite coated flies performed better than all other groups, and showed a permanent pinhole-free film, which prevented H₂O to diffuse into the fly material, providing a water tight coating. Moreover, the Al₂O₃ outer layer provided a hydrophobic surface that kept the fly floating throughout the experiment, even after forced submerging several times (>50 times).

### Example 22

### Permanent Nano-Composite Reinforcement with Hydrophilic Outer Layer

The aim of this experiment was to provide a permanent nano-coating for coating wet flies, streamers, salt water flies and other flies that are supposed to work under water, and which is water tight but hydrophilic, and therefore let the fly sink immediately in contact with the water surface.

In the current experiment 4 groups of identical flies (May fly no. 10, Midgarflyfish.com AS, Oslo, Norway); 1) untreated, 2) coated with Orvis® Mud (Orvis® Mud, Orvis Ltd, UK) sputter coating (108 Auto, Chressington Gold Coater) with gold (0.001 mbar, 40 mA, 30 sec) and 4) ALD coating with a composite layer consisting starting with 20 nm aluminum oxide (Al₂O₃), 5 nm TiO₂, 5 nm Al₂O₃, 5 nm TiO₂, 5 nm Al₂O₃, and ending 20 nm TiO₂ (total 60 nm of coating) at low temperature (<100 C) where tested.

The flies were weighted with a high precision balance ( 1/1000 g), dipped in water for several times with vigorous stirring, then dried by blowing strongly 5 times, and finally weighted again. By this mean, the intake of water of the flies when dragged under water could be measured in order to determine if the treatment increased their hydrophilic ability, increase in weight, time in water before hydrophilic effect disappear. Static contact angle was measure with ultrapure water (OCA 20, Digital Physic GmbH, Germany). The result is displayed in table 3.

TABLE 3
Result from hydrophilicity study

| | | | | Time in |
|---|---|---|---|---|
| | | | | water |
| | | | Sinking time | before |
| | | Contact | after being | hydrophilic |
| | Increase in | angle | place on a | effect |
| Treatment | weight (%) | (degrees) | water surface | disappear |
| Non-treated | 86 | 103 | >1 min | n.a. |
| coated with | 91 | 63 | 5-10 sec | 15-20 min |
| Orvis Mud ® | | | | |
| Sputter coated | 71 | 80 | 45-50 sec | n.a. |
| gold | | | | |
| ALD composite | 36 | 19 | Immediately | never |
| layer | | | | |

Conclusion: The non-treated fly floated and did not sink without active force, as expected. The sputter coating did not provide a film suitable for making flies hydrophilic, moreover this film did not provide a completely water tight layer. The flies coated with commercial Orvis Mud® performed according to manufacturing specifications, however due to solubility of the coating, the effect wore off within 20 minutes. The ALD composite coated flies performed better than all other groups, and showed a permanent pin hole free film, which prevented H₂O to diffuse into the fly material, providing a water tight coating. Moreover, the TiO₂ outer layer provided a hydrophilic surface that made the fly sink instantly, even after active submerging and drying several times (>100 times).

1. A terminal fishing tackle, comprising a core fiber and/or fabric at least partially coated with at least one homogenous, pin hole free and substantially amorphous metal oxide layer, wherein the coating has a thickness of 200 nm or less.

2. A terminal fishing tackle according to claim 1, wherein the thickness of said metal oxide layer is 100 nm or less.

3. A terminal fishing tackle according to claim 1, wherein the thickness of said metal oxide layer is between 5-100 nm.

4. A terminal fishing tackle according to claim 1, wherein said metal oxide layer comprises at least 75% titanium oxide and/or aluminum oxide, such as at least 80, 90, 95 or 99% titanium oxide and/or aluminum oxide.

5. A terminal fishing tackle according to claim 4, wherein said titanium oxide is selected from the group consisting of TiO, Ti₂O₃, Ti₃O₅, and TiO₂.

6. A terminal fishing tackle according to claim 4, wherein said aluminum oxide is selected from the group consisting of Al₂O₃.

7. A terminal fishing tackle according to claim 4, comprising at least two metal oxide layers, wherein at least one metal oxide layer comprises at least 75% titanium oxide and wherein at least one metal oxide layer comprises at least 75% aluminum oxide.

8. A terminal fishing tackle according to claim 1, wherein said metal oxide layer additionally comprises one or more compounds selected from the group consisting of N, C, S, Cl, F and/or one or more compounds selected from the group consisting of Cl, F and N, and/or one or more compounds selected from the group consisting of Ag, Au, Pd, Pt, Fe, C, Cl, F, Pb, Si, Zn, Zr, B, Br, Cr, Hg, Sr, Cu, I, Sn, Ta, W, Co, Mg, Mn and Cd and/or one or more compounds selected from the group consisting of SnO₂, CaSnO₃, WO₃, FeGaO₃, BaZrO₃, ZnO, Nb₂O₅, CdS, ZnO₂, SrBi₂O₅, BiAlVO₇, ZnInS₄, K₆Nb_{10.8030}, Si₃N₄, SiC, SiH₄, SiF₂, Si₂O and/or a combination of compounds selected from said groups of compounds, wherein said one or more compound(s) selected from one or more group(s) of compounds are dispersed substantially homogenous within said metal oxide layer.

9. A terminal fishing tackle according to claim 1, wherein said metal oxide nano-layer is selected from the group consisting of TiO₂ and Al₂O₃.

10. A terminal fishing tackle according to claim 1, selected from the group consisting of line, bait and/or fly.

11. A terminal fishing tackle according to claim 1, wherein the core fiber and/or fabric is selected from natural and/or synthetic fibres.

12. A terminal fishing tackle according to claim 1, wherein the core fiber and/or fabric is selected from the group consisting of polymer microspheres (PVC plastisol), glass microsphere, nylon monofilament (Polyamid, PA) nylon 6-6, nylon 5, 6, 10, polyethylene, Dacron and Dyneema (UHMWPE) copolymers or fluorocarbon, polyethylene terephthalate (PET), polyester, polypropylene (PP), polyvinyl, acrylic fibers, Polyurethane (PU), polyvinylchloride (PVC), polytetrafluoroethylene (PTFE), polyacrylate, gold, silver, copper, iron, aluminum, titanium, carbon, nickel, cobalt, zinc, vanadium, lead, animal fibers and hair such beaver, bull, bear, reindeer, cows, hare, alpaca, angora, camel hair, cashmere, catgut, chiengora, llama, mohair, bird feathers and fibers, silk, sinew, spider silk, wool, asbestos, basalt, mineral wool, and glass wool.

13. A terminal fishing tackle according to claim 1, wherein said metal oxide layer has hydrophobic, hydrophilic, super hydrophilic, waterproof, sealant, colour introducing, photocatalytic, UV-protecting, and/or anti-fouling properties.

14. A method for producing a terminal fishing tackle, comprising a core fiber and/or fabric which is at least partially coated with at least one homogenous and substantially amorphous metal oxide layer, wherein the coating has a thickness of 200 nm or less, using atomic layer deposition technique.

15. A method for reactivating and/or boosting the photo catalytic properties of said terminal fishing tackle of claim 14, by applying photo activation with high energy light and/or visible light to said metal oxide layer.

16. A method according to claim 15, wherein said high energy light is UV light, blue light or laser light.

17. A method for producing a terminal fishing tackle, comprising a core fiber and/or fabric which is at least partially coated with at least one homogenous, pin hole free and substantially amorphous metal oxide layer, wherein the coating has a thickness of 200 nm or less, said method comprising the steps of:
a) selecting a core material;
b) adding said metal oxide layer onto said core material and optionally
c) simultaneously with step b) adding one or more compounds to said metal oxide layer; said one or more compounds being dispersed substantially homogenous within said metal oxide layer.

18. A method according to claim 17, wherein said one or more compounds are added to said metal oxide layer by co-pulsing and/or mixing said compounds into said metal oxide layer.

19. A method for producing a terminal fishing tackle, comprising a core fiber and/or fabric which is at least partially coated with at least one homogenous, pin hole free and substantially amorphous metal oxide layer, wherein the coating has a thickness of 200 nm or less, said method comprising using ALD (Atomic Layer Deposition) technology for attaching said metal oxide layer onto said core material, and wherein said ALD reaction is performed at a reaction temperature of about 20-500° C.

20. A method according to claim 19, wherein said temperature is between 50 and 150° C.
